(19) United States
(12) Patent Application Publication
(10) Pub. No.: US 2025/0096770 A1
(43) Pub. Date: Mar. 20, 2025

(54) COMPOSITE SUBSTRATE AND METHOD FOR PRODUCING COMPOSITE SUBSTRATE

(71) Applicant: NGK INSULATORS, LTD., Nagoya-shi (JP)

(72) Inventors: Takahiro YAMADERA, Nagoya-shi (JP); Yuji HORI, Owariasahi-shi (JP)

(21) Appl. No.: 18/961,794

(22) Filed: Nov. 27, 2024

Related U.S. Application Data
(63) Continuation of application No. PCT/JP2023/015177, filed on Apr. 14, 2023.

(30) Foreign Application Priority Data
Jun. 27, 2022 (JP) 2022-102542

(51) Int. Cl. H03H 9/02; H03H 3/08

(52) U.S. Cl. CPC H03H 9/02574; H03H 3/08; H03H 9/02559

(57) ABSTRACT

A composite substrate includes: a support substrate having an upper surface and a lower surface that are opposed to each other; a piezoelectric layer arranged on the upper surface side of the support substrate; and an intermediate layer arranged between the support substrate and the piezoelectric layer, wherein, in an end portion of the support substrate on the upper surface side, a low crystalline region having a lower crystallinity as compared to a region positioned on the lower surface side is formed.

### CROSS-REFERENCE TO RELATED APPLICATIONS

This application is a continuation of International Application PCT/JP2023/015177, filed of Apr. 14, 2023, which claims the benefit of priority of Japanese Application No. 2022-102542, filed on Jun. 27, 2022, the entire contents of which are incorporated herein by reference.

### BACKGROUND OF THE INVENTION

### Technical Field

One or more embodiments of the present invention relates to a composite substrate and a method of producing a composite substrate.

### Background Art

For example, a filter utilizing a surface acoustic wave (SAW filter) has been used in an information communication device to extract an electric signal having any appropriate frequency. In recent years, in the field of the information communication device, a communication volume has sharply increased, and higher performance of the SAW filter is demanded. For example, in Non Patent Literature 1, there is disclosed a SAW filter using a substrate formed of a piezoelectric body, a silicon oxide film, and a silicon substrate.

### CITATION LIST

### Non Patent Literature

[NPL 1] Tsutomu Takai et al., “I.H.P. SAW Technology and its Application to Microacoustic Components (Invited),” Proceedings of International Ultrasonics Symposium, 2017

### SUMMARY OF THE INVENTION

However, still higher performance of the SAW filter is demanded.

In view of the foregoing, a primary object of the present invention is to provide a composite substrate that can contribute to achievement of higher performance of a SAW filter.
1. According to one embodiment of the present invention, there is provided a composite substrate, including: a support substrate having an upper surface and a lower surface that are opposed to each other; a piezoelectric layer arranged on the upper surface side of the support substrate; and an intermediate layer arranged between the support substrate and the piezoelectric layer, wherein, in an end portion of the support substrate on the upper surface side, a low crystalline region having a lower crystallinity as compared to a region positioned on the lower surface side is formed.
2. In the composite substrate according to the above-mentioned item 1, the low crystalline region may have a thickness of 30 nm or more.
3. In the composite substrate according to the above-mentioned item 1 or 2, the intermediate layer may include a silicon film.
4. In the composite substrate according to any one of the above-mentioned items 1 to 3, the intermediate layer may include, from the support substrate side, in this order, a first oxide layer, a silicon film, and a second oxide layer.
5. According to one embodiment of the present invention, there is provided a method of producing a composite substrate, including in this order: forming a damage region in an end portion of a support substrate on an upper surface side, the support substrate having the upper surface and a lower surface that are opposed to each other; and joining a piezoelectric substrate to the upper surface side of the support substrate via an intermediate layer.
6. In the method of producing a composite substrate according to the above-mentioned item 5, the forming of the damage region may be performed by blasting abrasive grains to the upper surface of the support substrate.
7. In the method of producing a composite substrate according to the above-mentioned item 5 or 6, the intermediate layer may include a silicon film formed by physical vapor deposition.

### Advantageous Effects of Invention

According to the embodiments of the present invention, for example, it is possible to contribute to achievement of higher performance of a SAW filter.

### BRIEF DESCRIPTION OF THE DRAWINGS

FIG. 1 is a schematic sectional view for illustrating the schematic configuration of a composite substrate according to one embodiment of the present invention.

FIG. 2A is a view for illustrating an example of a production process for the composite substrate according to one embodiment.

FIG. 2B is a view subsequent to FIG. 2A.

FIG. 2C is a view subsequent to FIG. 2B.

FIG. 2D is a view subsequent to FIG. 2C.

FIG. 2E is a view subsequent to FIG. 2D.

FIG. 3 is a sectional observation photograph of a composite substrate of Example 1.

FIG. 4A is an explanatory view of a pattern of a coplanar waveguide used in evaluation of a high-frequency characteristic.

FIG. 4B is a view for illustrating a part surrounded by the broken line of FIG. 4A in an enlarged manner.

FIG. 5 is a graph for showing evaluation results.

### DESCRIPTION OF THE EMBODIMENTS

Embodiments of the present invention are described below with reference to the drawings. However, the present invention is not limited to these embodiments. In addition, in the drawings, the width, thickness, shape, and the like of each portion may be schematically illustrated as compared to those in the embodiments in order to provide clearer description, but the drawings are merely examples and do not limit the interpretation of the present invention.

### A. Composite Substrate

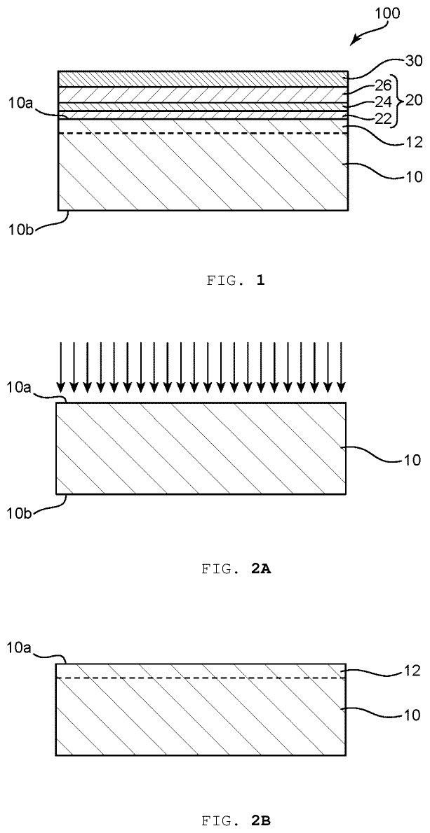

FIG. 1 is a schematic sectional view for illustrating the schematic configuration of a composite substrate according to one embodiment of the present invention. A composite substrate 100 includes a support substrate 10, an intermediate layer 20, and a piezoelectric layer 30 in this order. Specifically, the piezoelectric layer 30 is arranged on an upper surface 10a side of the support substrate 10 having the upper surface 10a and a lower surface 10b that are opposed to each other, and the intermediate layer 20 is arranged between the piezoelectric layer 30 and the support substrate 10.

A low crystalline region 12 is formed in an end portion of the support substrate 10 on the upper surface 10a side. The low crystalline region 12 has a state in which a crystallinity thereof is lower than that of a region positioned on the lower surface 10b side of the support substrate 10. The crystallinity of the support substrate 10 can be recognized through, for example, transmission electron microscope (TEM) observation. Through use of such support substrate, a high-performance surface acoustic wave element can be obtained. The low crystalline region 12 may be partially formed in the support substrate 10 in plan view, but is preferably formed over the entirety of the support substrate 10 in plan view.

The intermediate layer 20 preferably includes, for example, a silicon film from the viewpoint of obtaining a high-performance surface acoustic wave element. In the illustrated example, the intermediate layer 20 has a multi-layer structure including, from the support substrate 10 side, a first oxide layer 22, a silicon film 24, and a second oxide layer 26. The composite substrate 100 may further include any appropriate layer (not shown). The kinds, functions, number, combination, arrangement, and the like of such layers may be appropriately set in accordance with purposes.

The composite substrate 100 may be produced in any appropriate shape. In one embodiment, the substrate may be produced in the form of a so-called wafer. The size of the composite substrate 100 may be appropriately set in accordance with purposes. For example, the diameter of the wafer is from 100 mm to 200 mm.

### A-1. Support Substrate

The support substrate is typically formed of silicon. The kind or the like of the silicon for forming the support substrate is not particularly limited, but is preferably single crystal silicon. In addition, the silicon for forming the support substrate is preferably high resistance silicon (having a volume resistivity of 1,000 Ω·cm or more, for example). The silicon for forming the support substrate may be doped with a dopant such as phosphorus or boron.

The thermal expansion coefficient of a material for forming the support substrate is preferably smaller than the thermal expansion coefficient of a material for forming the piezoelectric layer. Such support substrate may suppress changes in shape and size of the piezoelectric layer at the time of a temperature change, and hence can suppress, for example, a change in frequency characteristic of a surface acoustic wave device to be obtained. For example, when the material for forming the support substrate is silicon, the relationship of the thermal expansion coefficients may be satisfied.

Any appropriate thickness may be adopted as the thickness of the support substrate. The thickness of the support substrate is, for example, from 100 μm to 1,000 μm.

The thickness of the low crystalline region of the support substrate is preferably 30 nm or more, more preferably 100 nm or more, still more preferably 300 nm or more. Meanwhile, the thickness of the low crystalline region is preferably 3 μm or less, and may be 2 μm or less or may be 1 μm or less. The thickness of the low crystalline region may correspond to a depth (distance) from the upper surface of the support substrate to a site at which the crystallinity changes. For example, the thickness of the low crystalline region may be an average of a distance from the upper surface 10a of the support substrate to an interface of the low crystal in any appropriate cross section.

### A-2. Intermediate Layer

The silicon film that may be included in the intermediate layer may include at least one selected from amorphous silicon and polycrystalline silicon. The thickness of the silicon film is preferably 5 nm or more and 2 μm or less, more preferably 50 nm or more and 1 μm or less.

Typically, the silicon film may be formed by physical vapor deposition such as sputtering.

Examples of a material for forming the oxide layer that may be included in the intermediate layer include silicon oxide, tantalum oxide (Ta₂O₅), and niobium oxide (Nb₂O₅). The thickness of the oxide layer (each of the first oxide layer and the second oxide layer) is preferably 50 nm or more and 3 μm or less, more preferably 100 nm or more and 2.5 μm or less, still more preferably 200 nm or more and 2 μm or less. As illustrated in FIG. 1, when the intermediate layer includes a plurality of oxide layers, the plurality of oxide layers may each have the same configuration material (e.g., or thickness), or have configurations different from each other.

The oxide layer may be formed by any appropriate method. The layer may be formed by, for example, physical vapor deposition, such as sputtering or ion beam-assisted deposition (IAD), chemical vapor deposition, or an atomic layer deposition (ALD) method.

### A-3. Piezoelectric Layer

Any appropriate piezoelectric material may be used as a material for forming the piezoelectric layer. A single crystal having the composition of LiAO₃ is preferably used as the piezoelectric material. Herein, A represents one or more kinds of elements selected from niobium and tantalum. Specifically, LiAO₃ may be lithium niobate (LiNbO₃), lithium tantalate (LiTaO₃), or a lithium niobate-lithium tantalate solid solution.

In the case where the piezoelectric material is lithium tantalate, for example, when the X-axis (crystal axis) of the piezoelectric material is defined as the direction (X₁) in which a surface acoustic wave propagates, it is preferred that the direction toward which the piezoelectric layer faces when rotated from the Y-axis thereof toward the Z-axis thereof by from 32° to 55° (e.g., 42°) correspond to a direction (X₃) perpendicular to the main surface of the piezoelectric layer, specifically, be (180°, 58° to 35°, 180°) in Euler angle notation.

In the case where the piezoelectric material is lithium niobate, for example, when the X-axis (crystal axis) of the piezoelectric material is defined as the direction (X₁) in which a surface acoustic wave propagates, it is preferred that the direction toward which the piezoelectric layer faces when rotated from the Z-axis thereof toward the −Y-axis thereof by from 0° to 40° (e.g., 37.8°) correspond to a direction (X₃) perpendicular to the main surface of the piezoelectric layer, specifically, be (0°, 0° to 40°, 0°) in Euler angle notation. In addition, in the case where the piezoelectric material is lithium niobate, for example, when the X-axis (crystal axis) of the piezoelectric material is defined as the direction (X₁) in which a surface acoustic wave propagates, it is preferred that the direction toward which the piezoelectric layer faces when rotated from the Y-axis thereof toward the Z-axis thereof by from 40° to 65° correspond to a direction (X₃) perpendicular to the main surface of the piezoelectric layer, specifically, be (180°, 50° to 25°, 180°) in Euler angle notation.

The thickness of the piezoelectric layer may be set to any appropriate thickness in accordance with use methods or purposes of the composite substrate. The thickness of the piezoelectric layer is, for example, 0.2 μm or more and 30 μm or less, and is preferably 0.2 μm or more and 5 μm or less.

### A-4. Production Method

A method of producing a composite substrate according to one embodiment of the present invention includes: forming a damage region in an end portion of a support substrate on an upper surface side, the support substrate having the upper surface and a lower surface that are opposed to each other; and joining, via an intermediate layer, a piezoelectric substrate to the upper surface side of the support substrate in which the damage region is formed.

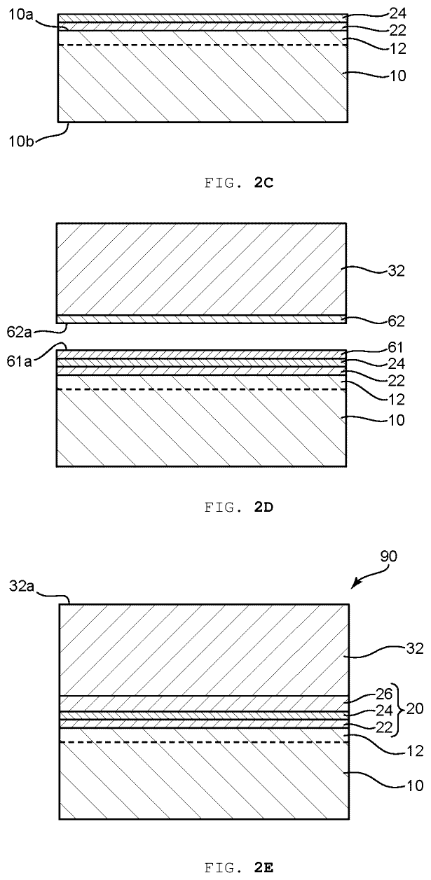

FIG. 2A to FIG. 2E are each a view for illustrating an example of a production process for the composite substrate according to one embodiment.

FIG. 2A is an illustration of a state in which surface treatment is performed from the upper surface 10a side of the support substrate 10 having the upper surface 10a and the lower surface 10b that are opposed to each other, and FIG. 2B is an illustration of a state in which the damage region (low crystalline region) 12 is formed in the end portion of the support substrate 10 on the upper surface 10a side. The low crystalline region 12 may be satisfactorily formed by performing, for example, blasting using abrasive grains. Specifically, the support substrate 10 may be subjected to blasting to reduce its crystallinity, and thus a region having a low crystallinity may be formed. Examples of a material for forming the abrasive grains to be blasted include alumina and silicon carbide (SiC). An average particle diameter of the abrasive grains to be blasted is preferably from 1 μm to 7 μm. The low crystalline region 12 may be partially formed in the upper surface 10a of the support substrate 10, but is preferably formed over the entirety of the upper surface 10a.

The formation of the low crystalline region 12 may cause the upper surface 10a of the support substrate 10 to have an uneven shape (not shown). An arithmetic mean roughness Sa of the upper surface 10a of the support substrate 10 after the blasting may be, for example, 1 nm or more, may be 1 nm or more and 50 nm or less, or may be 1 nm or more and 30 nm or less. The arithmetic mean roughness Sa is an average value of absolute values of heights of respective points in a defined region, and is calculated by the following equation. The arithmetic mean roughness Sa corresponds to a parameter obtained by expanding the arithmetic mean roughness Ra on a roughness profile defined in JIS B 0601 to a plane, and is a parameter defined in ISO 25178.

$$Sa = \frac{1}{A} \int {\int }_{A} \vert Z ( x , y ) \vert dxdy$$

FIG. 2C is an illustration of a state in which the first oxide layer 22 and the silicon film 24 are formed on the upper surface 10a of the support substrate 10 after the blasting, and FIG. 2D is an illustration of a state in which a first layer 61 is formed on the silicon film 24 of the support substrate 10 and a second layer 62 is formed on one side of a piezoelectric substrate 32. The first layer 61 and the second layer 62 can be formed by the above-mentioned film forming method for the oxide layer. In one embodiment, a material for forming the first layer 61 and a material for forming the second layer 62 are substantially the same. For example, the first layer 61 and the second layer 62 are formed by sputtering using the same target and under the same condition. As long as joining to be described later may be performed, any appropriate material may be selected as each of the material for forming the first layer 61 and the material for forming the second layer 62. In addition, each of the thickness of the first layer 61 and the thickness of the second layer 62 may be set to any appropriate thickness.

FIG. 2E is an illustration of a state in which a joining surface of the support substrate 10 on which the first oxide layer 22, the silicon film 24, and the first layer 61 are formed and a joining surface of the piezoelectric substrate 32 on which the second layer 62 is formed are brought into contact with each other to be joined to each other (directly joined to each other), and thus a joined body 90 is formed. The first layer 61 and the second layer 62 are joined to each other to form the second oxide layer 26, and thus the joined body 90 in which the support substrate 10 and the piezoelectric substrate 32 are joined to each other via the intermediate layer 20 is obtained. Typically, a surface 32a of the piezoelectric substrate 32 of the obtained joined body 90 is subjected to treatment, such as grinding or polishing, so as to obtain the piezoelectric layer having the above-mentioned desired thickness. Thus, the composite substrate 100 illustrated in FIG. 1 can be obtained.

At the time of the above-mentioned joining, the joining surfaces are preferably subjected to flattening treatment in advance. In the example illustrated in FIG. 2D, the joining surfaces are a surface 61a of the first layer 61 and a surface 62a of the second layer 62. In particular, the surface 61a of the first layer 61 may have an uneven shape conforming to the uneven shape of the upper surface 10a of the support substrate 10, and hence the surface 61a of the first layer 61 is preferably smoothed by flattening treatment. The arithmetic mean roughness Ra of each of the joining surfaces is preferably 1 nm or less, more preferably 0.3 nm or less. Such arithmetic mean roughness Ra may be achieved by, for example, mirror polishing through chemical mechanical polishing (CMP). The arithmetic mean roughness Ra is a value measured with an atomic force microscope (AFM) in a field of view measuring 10 μm×10 μm.

When the support substrate 10 and the piezoelectric substrate 32 are brought into contact with each other, the joining surface on the support substrate 10 side and the joining surface on the piezoelectric substrate 32 side are preferably subjected to activation treatment in advance. In one embodiment, the activation treatment is performed by plasma irradiation. Examples of a gas included in an atmosphere at the time of the activation treatment include oxygen, nitrogen, hydrogen, and argon. Those gases may be used alone or in combination thereof (as a mixed gas). Nitrogen is preferably used.

An atmospheric pressure at the time of the activation treatment by plasma irradiation is preferably from 10 Pa to 80 Pa, more preferably from 30 Pa to 80 Pa. Energy at the time of the plasma irradiation is preferably from 30 W to 150 W, more preferably from 60 W to 120 W. A time period of the plasma irradiation is preferably from 5 seconds to 30 seconds.

Preferably, after the joining surface on the support substrate 10 side and the joining surface on the piezoelectric substrate 32 side are brought into contact with each other, the joined body is preferably heated. The heating allows the joining strength between the support substrate 10 and the piezoelectric substrate 32 to be further improved. A heating temperature is, for example, from 100° C. to 400° C. A heating time period is, for example, from 1 hour to 25 hours. Each of the contact and the heating may be performed under an atmosphere of an inert gas, such as nitrogen or argon, or may be performed in the air atmosphere.

In one embodiment, the heating includes a first heating step and a second heating (annealing) step in this order. In the first heating step, the above-mentioned joined body is heated from room temperature until the temperature reaches a temperature T1 (e.g., from 100° C. to 150° C.). In the second heating step, the joined body is placed under a condition of a temperature T2 for a predetermined time period (e.g., from 3 hours to 25 hours). The temperature T2 is, for example, 180° C. or more, and may be 200° C. or more, 230° C. or more, 250° C. or more, or 270° C. or more. Meanwhile, the temperature T2 is preferably 350° C. or less, more preferably 300° C. or less from the viewpoint of suppressing damage to the joined body, for example. After the second heating step, typically, the joined body is naturally cooled.

At the time of the film formation and the joining described above, the surface of each layer is preferably washed for, for example, removing a residue of a polishing agent, a work-affected layer, or the like. A method for the washing is, for example, wet washing, dry washing, or scrub washing. Of those, scrub washing is preferred because the surface can be simply and efficiently washed. A specific example of the scrub washing is a method including washing the surface in a scrub washing machine with a detergent (e.g., a SUNWASH series manufactured by Lion Corporation) and then with a solvent (e.g., a mixed solution of acetone and isopropyl alcohol (IPA)).

Each layer for forming the intermediate layer may be formed on the support substrate side, or may be formed on the piezoelectric substrate side. In the illustrated example, a part of the layers for forming the intermediate layer is formed on the support substrate side, and a part of the layers for forming the intermediate layer is formed on the piezoelectric substrate side. Those layers are joined to each other to obtain the composite substrate. However, unlike the illustrated example, for example, the support substrate 10 and the piezoelectric substrate 32 may be joined to each other without forming the second layer 62 on the piezoelectric substrate 32 side (through use of the first layer 61 itself as the second oxide layer 26) to obtain the composite substrate. In addition, for example, all of the layers for forming the intermediate layer may be formed on the piezoelectric substrate side, and the piezoelectric substrate on which the intermediate layer is formed and the support substrate may be joined to each other to obtain the composite substrate.

### B. Surface Acoustic Wave Element

The above-mentioned composite substrate according to the embodiment of the present invention may be used in a surface acoustic wave element. The surface acoustic wave element typically includes the composite substrate and an electrode (comb electrode) arranged on the piezoelectric layer side of the composite substrate. Such surface acoustic wave element is suitably used as, for example, a SAW filter in a communication device such as a cellular phone.

### EXAMPLES

The present invention is specifically described below by way of Examples. However, the present invention is not limited by these Examples. The arithmetic mean roughness Sa is a value measured by a measurement method described below.

### <Arithmetic Mean Roughness Sa>

The arithmetic mean roughness Sa was measured with an atomic force microscope (AFM) in a field of view measuring 10 μm×10 μm in conformity to ISO 25178.

### Example 1

A high-resistance (>2 kΩ·cm) silicon substrate having a diameter of 150 mm and a thickness of 0.50 mm in which the upper surface and the lower surface thereof were subjected to mirror polishing was prepared.

In addition, a 42° Y-cut black lithium tantalate (LT) substrate having a diameter of 150 mm and a thickness of 0.25 mm in which a front surface and a back surface thereof were subjected to mirror polishing was prepared.

The upper surface of the silicon substrate was subjected to blasting through use of abrasive grains (alumina particles) having an average particle diameter of 2 μm. The arithmetic mean roughness Sa of the surface subjected to blasting was from 1.8 nm to 27.5 nm.

After that, the silicon substrate subjected to blasting was introduced into a chamber of a sputtering apparatus (manufactured by SHINCRON CO., LTD., “RAS-1100BII”) so that a silicon oxide layer (first oxide layer) having a thickness of about 500 nm was formed on the surface of the silicon substrate subjected to blasting, and subsequently a silicon film having a thickness of about 100 nm was formed on the silicon oxide layer. After the silicon film was formed on the silicon substrate, the LT substrate was introduced into the chamber of the sputtering apparatus so that, under the conditions similar to those for the first oxide layer, a silicon oxide layer having a thickness of about 500 nm was formed on each of the silicon film of the silicon substrate and the LT substrate surface. In the film formation, a Si target was used, and an oxygen gas was introduced into the chamber as an oxygen source. By adjusting an oxygen gas introduction amount, the total pressure and oxygen partial pressure of the atmosphere in the chamber were adjusted, and each layer was formed under the following conditions.
Rate: 0.3 nm/sec
Pressure in the chamber at the time of film formation: 0.3 Pa

After the film formation, each of the silicon oxide layers of the silicon substrate and the LT substrate was polished by about 100 nm through CMP treatment to be smoothed (Ra: about 0.2 nm).

The joining surface (surface on the silicon oxide layer side) of the silicon substrate and the joining surface (surface on the silicon oxide layer side) of the LT substrate were washed, and particles thereon were removed. After that, those substrates were introduced into a plasma activation chamber, and thus the joining surfaces of the respective substrates were activated. Specifically, the activation treatment using nitrogen gas plasma (energy: 100 W) was performed at room temperature for 10 seconds.

Next, the activated surfaces of both the substrates were stacked on each other at room temperature in the air atmosphere to obtain the joined body.

Next, the obtained joined body was put into an oven (120° C.) of a nitrogen atmosphere, and heated for 10 hours. After that, the LT substrate of the joined body (composite substrate) taken out from the oven was subjected to grinding and lapping and to CMP treatment, to thereby obtain an LT layer having a thickness of 1 μm. Thus, the composite substrate was obtained.

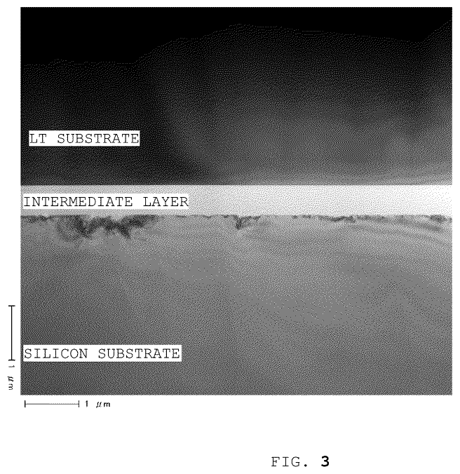

The cross section of the composite substrate obtained in Example 1 was observed with a transmission electron microscope (manufactured by Hitachi High-Tech Corporation, “H-9500”) under the conditions of an accelerating voltage of 200 kV and a total magnification of 25,000 times. As a result, as shown in FIG. 3, it was confirmed that, in the end portion of the silicon substrate on the upper surface side, a region (damage region) having a lower crystallinity as compared to a region positioned on the lower surface side thereof was formed. The damage region had a depth of 50 nm or more from the upper surface of the silicon substrate.

### Example 2

A composite substrate was obtained in the same manner as in Example 1 except that a tantalum oxide layer was formed in place of the silicon oxide layer on the silicon film of the silicon substrate and on the LT substrate surface. The film formation of the tantalum oxide layer was performed in the same manner as in the film formation of the silicon oxide layer except that a Ta target was used in place of the Si target.

### Example 3

A composite substrate was obtained in the same manner as in Example 2 except that a tantalum oxide layer was formed in place of the silicon oxide layer as the first oxide layer formed on the silicon substrate. The film formation of the tantalum oxide layer was performed in the same manner as in the film formation of the silicon oxide layer except that a Ta target was used in place of the Si target.

### Example 4

A composite substrate was obtained in the same manner as in Example 1 except that no silicon film or silicon oxide layer was formed on the first oxide layer of the silicon substrate, and no silicon oxide layer was formed on the LT substrate.

### Comparative Example 1

A composite substrate was obtained in the same manner as in Example 1 except that the silicon substrate was not subjected to blasting, no silicon film or silicon oxide layer was formed on the first oxide layer of the silicon substrate, and no silicon oxide layer was formed on the LT substrate.

### <Evaluation>

The high-frequency characteristic of the composite substrate of each of Examples and Comparative Example was evaluated.

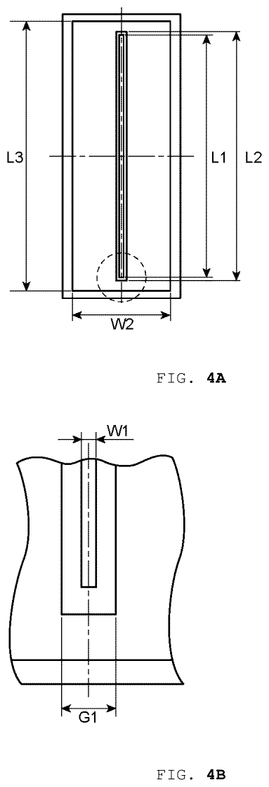

A Au film having a thickness of 2 μm was formed on the LT layer of the resultant composite substrate by sputtering. After that, the Au film was subjected to lithography and ion milling to form a coplanar waveguide (CPW). Details of the formed coplanar waveguide are as shown in FIG. 4A and FIG. 4B. In FIG. 4A and FIG. 4B, L1 is 2,100 μm, L2 is 2,500 μm, L3 is 3,100 μm, W1 is 60 μm, W2 is 3,000 μm, and G1 is 340 μm.

A high-frequency probe (TP40-GSG-250-N-L) manufactured by Technoprobe Inc. was brought into contact with both end portions of the resultant coplanar waveguide in a lengthwise direction thereof, and RF power of 19 dBm was input by a signal generator to measure the second harmonic wave with a spectrum analyzer manufactured by Keysight Technologies.

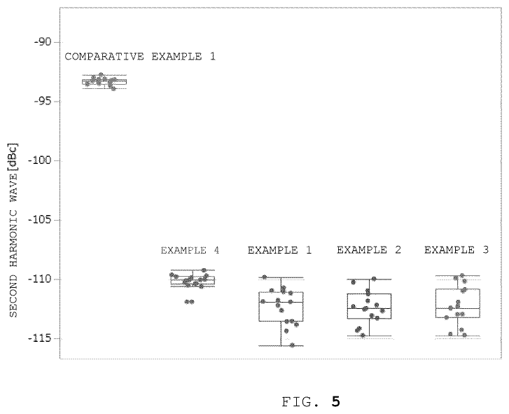

The second harmonic wave was measured at 15 sites on the surface of each substrate. The evaluation results are shown in FIG. 5.

It is found that the second harmonic wave was suppressed in each Example.

### INDUSTRIAL APPLICABILITY

Typically, the composite substrate according to the embodiments of the present invention may be suitably used for an acoustic wave device.

What is claimed is:

1. A composite substrate, comprising:
a support substrate having an upper surface and a lower surface that are opposed to each other;
a piezoelectric layer arranged on the upper surface side of the support substrate; and
an intermediate layer arranged between the support substrate and the piezoelectric layer,
wherein, in an end portion of the support substrate on the upper surface side, a low crystalline region having a lower crystallinity as compared to a region positioned on the lower surface side is formed.

2. The composite substrate according to claim 1, wherein the low crystalline region has a thickness of 30 nm or more.

3. The composite substrate according to claim 1, wherein the intermediate layer includes a silicon film.

4. The composite substrate according to claim 1, wherein the intermediate layer includes, from the support substrate side, in this order, a first oxide layer, a silicon film, and a second oxide layer.

5. A method of producing a composite substrate, comprising in this order:
forming a damage region in an end portion of a support substrate on an upper surface side, the support substrate having the upper surface and a lower surface that are opposed to each other; and
joining a piezoelectric substrate to the upper surface side of the support substrate via an intermediate layer.

6. The method of producing a composite substrate according to claim 5, wherein the forming of the damage region is performed by blasting abrasive grains to the upper surface of the support substrate.

7. The method of producing a composite substrate according to claim 5, wherein the intermediate layer includes a silicon film formed by physical vapor deposition.
